(19) United States
(12) Patent Application Publication
(10) Pub. No.: US 2018/0294318 A1
(43) Pub. Date: Oct. 11, 2018

(54) ORGANIC ELECTROLUMINESCENCE DEVICE AND MANUFACTURING METHOD FOR THE SAME

(71) Applicant: WUHAN CHINA STAR OPTOELECTRONICS TECHNOLOGY CO., LTD., Wuhan, Hubei (CN)

(72) Inventors: Tien-wang HUANG, Shenzhen, Guangdong (CN); Lei CUI, Shenzhen, Guangdong (CN)

(73) Assignee: Wuhan China Star Optoelectronics Technology Co., Ltd., Wuhan, Hubei (CN)

(21) Appl. No.: 15/522,282

(22) PCT Filed: Mar. 28, 2017
(86) PCT No.: PCT/CN2017/078345

§ 371 Date: Apr. 26, 2017

(30) Foreign Application Priority Data
Feb. 20, 2017 (CN) 201710088649.7

(51) Int. Cl. H01L 27/32; H01L 51/00; H01L 51/56; G06F 3/041

(52) U.S. Cl. CPC H01L 27/323; H01L 27/3244; H01L 51/0097; H01L 51/56; G06F 2203/04103; H01L 2251/5338; H01L 2227/323; G06F 2203/04102; G06F 3/0412

(57) ABSTRACT

An organic electroluminescence device includes: a substrate; a switching layer disposed on the substrate, and the switching layer includes multiple switching elements arranged as a matrix; an organic electroluminescence layer disposed on the switching layer, the organic electroluminescence layer includes multiple organic electroluminescence elements arranged as a matrix, the organic electroluminescence elements are controlled to emit light through corresponding switching elements; a first planarization layer disposed on the substrate, covering on the switching layer and the organic electroluminescence layer; and a touch layer disposed on the substrate and covering on the first planarization layer. The present invention also provides a manufacturing method for the organic electroluminescence device. Using the first planarization layer to directly encapsulate the switching layer and the organic electroluminescence layer, and no additional Thin Film Encapsulation layer is required. Accordingly, the thickness of the production is reduced and the cost is saved at the same time.

### BACKGROUND OF THE INVENTION

### 1. Field of the Invention

The present invention relates to organic electroluminescence technology field, and more particularly to an organic electroluminescence device and a manufacturing method for the same.

### 2. Description of Related Art

In the recent year, the Organic Light-Emitting Diode (OLED) is a very hot emerging flat display device both at home and abroad. The reason is that the OLED display device has characters of self-luminous, wide viewing angle, short response time, high luminous efficiency, wide color gamut, low operating voltage, thin thickness, can be made in a large size, flexible panel and simple process. Besides, the OLED display device also has a low cost potential.

In the manufacturing process of the flexible OLED display device, the Thin Film Encapsulation (TFE) method is one of the most suitable packaging methods. Currently, the Thin Film Encapsulation method alternatively deposits a polymer organic film and an inorganic film on a surface of the OLED. The inorganic film has a good water and oxygen barrier property, and the polymer organic film can absorb the stress between a dispersion layer and a layer well so as to avoid a dense inorganic film to generate a crack to decrease the water and oxygen barrier property.

In a touch display device adopting a flexible OLED display device, usually, a planarization layer (PLN) is added on a TFE layer. Then, a touch layer is disposed on the planarization layer in order to realize a touch function. However, the manufacturing process is increased and a thickness of the production is also increased.

### SUMMARY OF THE INVENTION

The present invention provides an organic electroluminescence device and manufacturing method for the same, which can reduce the manufacturing process and decrease the thickness of the production at the same time.

According to one aspect of the present invention, an organic electroluminescence device is provided, and comprising: a substrate; a switching layer disposed on the substrate, and the switching layer includes multiple switching elements arranged as a matrix; an organic electroluminescence layer disposed on the switching layer, the organic electroluminescence layer includes multiple organic electroluminescence elements arranged as a matrix, the organic electroluminescence elements are controlled to emit light through corresponding switching elements; a first planarization layer disposed on the substrate, covering on the switching layer and the organic electroluminescence layer; and a touch layer disposed on the substrate and covering on the first planarization layer.

Optionally, the switching element includes: an active layer disposed on the substrate; a gate insulation layer disposed on the active layer; a gate electrode disposed on the gate insulation layer; an interlayer dielectric layer disposed on the substrate, covering on the active layer, the gate insulation layer and the gate electrode, wherein the interlayer dielectric layer is provided with a first vias hole, and the first vias hole exposes the active layer; a source electrode and a drain electrode disposed on the interlayer dielectric layer, wherein the source electrode and the drain electrode are respectively contacted with the active layer which is exposed through the first vias hole; and a second planarization layer disposed on the interlayer dielectric layer, and covering on the source electrode and the drain electrode, wherein the second planarization layer is provided with a second vias hole, and the second vias hole exposes the drain electrode.

Optionally, the switching element further includes: a buffering layer disposed between the active layer and the substrate and between the interlayer dielectric layer and the substrate.

Optionally, a material of the active layer is amorphous silicon, low temperature polysilicon, carbon nanotube, graphene or metal oxide semiconductor.

Optionally, the electroluminescence element comprises: a bottom electrode disposed on the second planarization layer, and the bottom electrode is contacted with the exposed drain electrode through the second vias hole; a pixel definition layer disposed on the second planarization layer and covering on the bottom electrode, the pixel definition layer has a third vias hole, and the third vias hole exposes the bottom electrode; an organic light-emitting layer group disposed on the exposed bottom electrode; and a top electrode disposed on the organic light-emitting layer group; wherein, the first planarization layer is disposed on the pixel definition layer, and covering on the top electrode.

Optionally, from the bottom electrode to the top electrode, the organic light-emitting layer group sequentially includes: a hole injection layer, a hole transport layer, an emitting layer, an electrode transport layer and an electrode injection layer.

Optionally, the touch layer includes: a first insulation layer disposed on the substrate and covering on the first planarization layer; a touch electrode layer disposed on the first insulation layer; and a second insulation layer disposed on the touch electrode layer.

Optionally, the substrate is a flexible substrate.

Optionally, the substrate is transparent, translucent or opaque.

According to another aspect of the present invention, a manufacturing method for the organic electroluminescence device is also provided, and comprising: providing a substrate; forming multiple switching elements arranged as a matrix on the substrate in order to form a switching layer; forming multiple organic electroluminescence elements arranged as a matrix on the switching layer in order to form an organic electroluminescence layer, and each organic electroluminescence element is controlled to emit light by a corresponding switching element; forming a first planarization layer that directly covers on the switching layer and the organic electroluminescence layer on the substrate; and forming a touch layer that directly covers on the first planarization layer on the substrate.

The beneficial effect of the present invention, the present invention adopts the first planarization layer to directly encapsulate the switching layer and the organic electroluminescence layer, and no additional Thin Film Encapsulation (TFE) layer is required. Accordingly, the thickness of the production is reduced and the cost is saved at the same time.

### BRIEF DESCRIPTION OF THE DRAWINGS

Through following to combine figures to describe in detail, the above, the other purposes, the features and benefits of the exemplary embodiment of the present disclosure will become clearer, wherein:

FIG. 1 is a schematic diagram of an organic electroluminescence device according to an embodiment of the present invention;

FIG. 2 is a schematic diagram of a switching device, an organic electroluminescence device and a touch layer; and

FIG. 3 is a flow chart of a manufacturing method for an organic electroluminescence device according to an embodiment of the present invention.

### DETAILED DESCRIPTION OF THE PREFERRED EMBODIMENT

The following content combines with the drawings and the embodiment for describing the present invention in detail. However, many other forms can be used to implement the present invention. Besides, the present invention should not be interpreted to be limit in the specific embodiment described here. On the contrary, the embodiments provided here are used for explaining the operation principle and practical application such that person skilled in the art can under various embodiments of the present invention and various modification suitable for specific applications.

In the figures, in order to illustrate the devices clearly, thickness of the layers and regions are enlarged. A same numeral in the entire specification and figures represents a same device.

It can also be understood that when a layer or an element is called be to “above” or “on” another element or layer, the layer or the element can directly form on another layer or the element or an intermediate element can be existed. Optionally, when an element is called “directly on” another element, no intermediate element is existed.

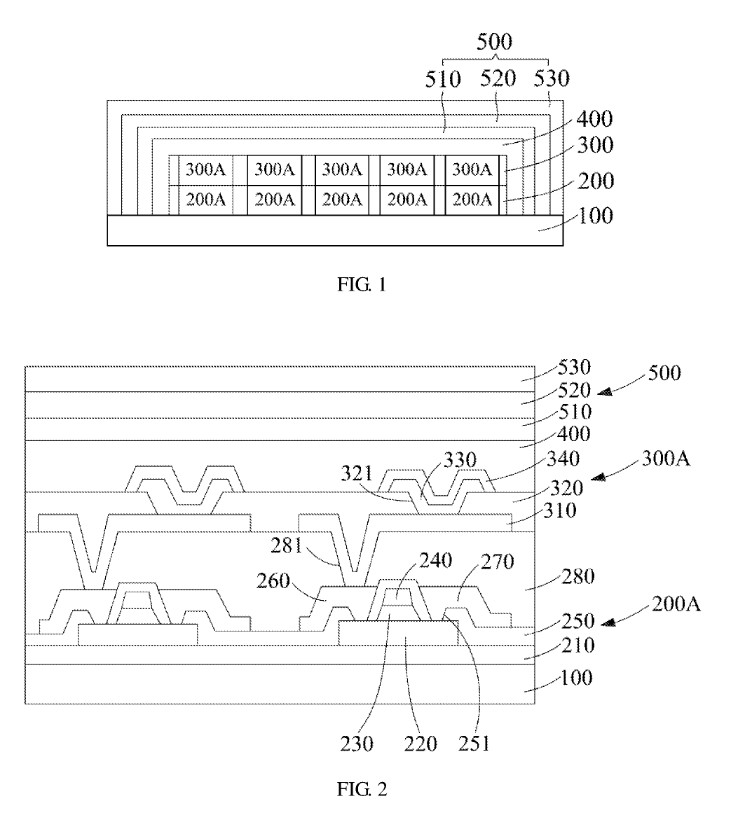

FIG. 1 is a schematic diagram of an organic electroluminescence device according to an embodiment of the present invention.

With reference to FIG. 1, the organic electroluminescence device according to an embodiment of the present invention includes: a substrate 100, a switching layer 200, and an organic electroluminescence layer 300, a first planarization layer (PLN) 400 and a touch layer 500.

The substrate 100 is a flexible substrate, which can be transparent, translucent or opaque. For observing a light-emitting of the organic electroluminescence layer 300 through the substrate 100, the substrate 100 can be transparent or translucent. For not observing a light-emitting of the organic electroluminescence layer 300 through the substrate 100, the substrate 100 can be transparent, translucent or opaque.

The switching layer 200 is disposed on the substrate 100. The switching layer 200 includes multiple switching elements 200A arranged as a matrix; In other words, the switching layer 200 is formed by the multiple switching elements 200A arranged as a matrix.

The organic electroluminescence layer 300 is disposed on the switching layer 200, and the organic electroluminescence layer 300 includes multiple organic electroluminescence elements 300A arranged as a matrix; in other words, the organic electroluminescence layer 300 is formed by the electroluminescence elements 300A arranged as a matrix. Each electroluminescence element 300A is controlled to emit a light through a corresponding switching element 200A.

The first planarization layer 400 is disposed on the substrate 100, and the first planarization layer 400 directly covering on the switching layer 200 and the organic electroluminescence layer 300. It should be noted that the first planarization layer 400 can be formed by an organic or an inorganic insulation material.

The touch layer 500 is disposed on the substrate 100, and the touch layer 500 covers on the first planarization layer 400.

In the present embodiment, the first planarization layer 400 directly encapsulates the switching layer 200 and the organic electroluminescence layer 300, and no additional Thin Film Encapsulation (TFE) layer is required. Accordingly, the thickness of the production is reduced and the cost is saved at the same time.

The following content will describe the specific structure of the switching element 200A, the electroluminescence element 300A and the touch layer 500 in detail. FIG. 2 is a schematic diagram of a switching device, an organic electroluminescence device and a touch layer.

With reference to FIG. 1 and FIG. 2, the switching element 200A includes: a buffering layer 210, an active layer 220, a gate insulation layer 230, a gate electrode 240, an interlayer dielectric layer (ILD) 250, a source electrode 260, a drain electrode 270 and a second planarization layer (PLN) 280.

The buffering layer 210 is disposed on the substrate 100. Here, as another embodiment of the present invention, the buffering layer 210 can be omitted.

The active layer 220 is disposed on the buffering layer 210. It should be noted that when the buffering layer 210 is omitted, the active layer 220 is directly disposed on the substrate 100. The material of the active layer 220 can be amorphous silicon, low temperature polysilicon, carbon nanotube, graphene or metal oxide semiconductor.

The gate insulation layer 230 is disposed on the active layer 220. The gate electrode 240 is disposed on the gate insulation layer 230. The interlayer dielectric layer 250 is disposed on the buffering layer 210. The interlayer dielectric layer 250 covers on the active layer 220, the gate insulation layer 230 and the gate electrode 240. It should be noted that when the buffering layer 210 is omitted, the interlayer dielectric layer 250 can be directly disposed on the substrate 100, and the interlayer dielectric layer 250 covers on the active layer 220, the gate insulation layer 230 and the gate electrode 240.

Furthermore, the interlayer dielectric layer 250 is etched with a first vias hole 251, the first vias hole 251 exposes the active layer 220.

The source electrode 260 and the drain electrode 270 are disposed on the interlayer dielectric layer 250, and the source electrode 260 and the drain electrode 270 are respectively contacted with the exposed active layer 220 through corresponding first vias holes 251.

The second planarization layer 280 is disposed on the interlayer dielectric layer 250, and the second planarization layer 280 covers on the source electrode 260 and the drain electrode 270. Furthermore, the second planarization layer 280 is etched with a second vias hole 281, and the second vias hole 281 exposes the drain electrode 270.

The electroluminescence element 300A includes: a bottom electrode 310, a pixel definition layer (PDL) 320, an organic light-emitting layer group 330 and a top electrode 340.

The bottom electrode 310 is disposed on the second planarization layer 280, and the bottom electrode 310 is contacted with the exposed drain electrode 270 through the second vias hole 281. The bottom electrode 310 is usually disposed as an anode. The bottom electrode 310 is also a reflector. When observing the organic light-emitting layer 330 through the substrate 100, the bottom electrode 310 is made of a metal having a reflective property, and should be thin enough such that the metal is partially transparent under a wavelength of an emitting light, which is also translucent. Or, the bottom electrode 310 is made of a transparent metal oxide such as indium tin oxide or zinc oxide. When observing the organic light-emitting layer 330 to emit light through the top electrode 340, the bottom electrode 310 is made of a metal having a reflective property, and should be thick enough such that the metal is opaque and fully reflective.

The pixel definition layer 320 is disposed on the second planarization layer 280, and the pixel definition layer 320 covers on the bottom electrode 310. Furthermore, the pixel definition layer 320 is etched with a third vias hole 321, and the third vias hole 321 exposes the bottom electrode 310.

The organic light-emitting layer group 330 is disposed on the exposed bottom electrode 310. The top electrode 340 is disposed on the organic light-emitting layer group 330. The first planarization layer 400 is disposed on the pixel definition layer 320, and the first planarization layer 400 covers on the top electrode 340.

The top electrode 340 is usually disposed as a cathode. The top electrode 340 is also a reflector. When observing the organic light-emitting layer group 330 through the top electrode 340, the top electrode 340 is made of a metal having a reflective property, and should be thin enough such that the metal is partially transparent under a wavelength of an emitting light, which is also translucent. Or, the top electrode 340 is made of a transparent metal oxide such as indium tin oxide or zinc oxide. When observing the organic light-emitting layer group 330 to emit light through the substrate 100, the top electrode 340 is made of a metal having a reflective property, and should be thick enough such that the metal is opaque and fully reflective.

As an embodiment of the present invention, from the bottom electrode 310 to the top electrode 340, the organic light-emitting layer group 330 sequentially includes: a hole injection layer (HIL), a hole transport layer (HTL), an emitting layer (EML), an electrode transport layer (ETL) and an electrode injection layer (EIL), but the present invention is not limited. Wherein, the above structure can be made of appropriate material, no more repeating.

The touch layer 500 includes: a first insulation layer 510, a touch electrode layer 520 and a second insulation layer 530. Here, the first insulation layer 510 covers on the first planarization layer 400; the touch electrode layer 520 covers on the first insulation layer 510; the second insulation layer 530 covers on the touch electrode layer 520.

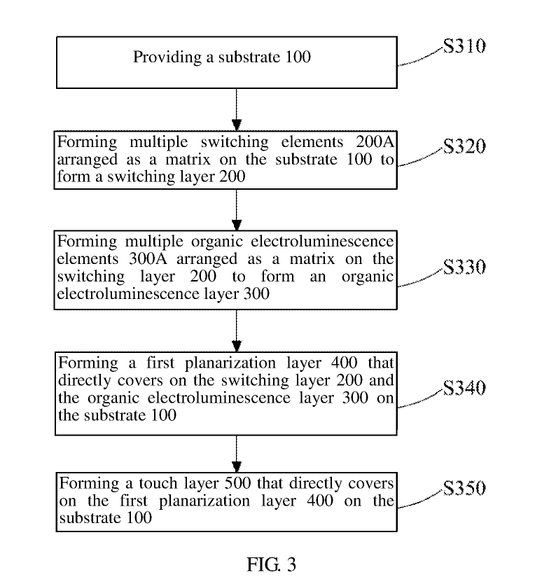

FIG. 3 is a flow chart of a manufacturing method for an organic electroluminescence device according to an embodiment of the present invention.

With reference to FIG. 1 to FIG. 3, a manufacturing method for the organic electroluminescence device according to an embodiment of the present invention comprises:

S310: providing a substrate 100;

S320: forming multiple switching elements 200A arranged as a matrix on the substrate 100 in order to form a switching layer 200;

S330: forming multiple organic electroluminescence elements 300A arranged as a matrix on the switching layer 200 in order to form an organic electroluminescence layer 300. Wherein, each organic electroluminescence element 300A is controlled to emit light by a corresponding switching element 200A;

S340: forming a first planarization layer 400 that directly covers on the switching layer 200 and the organic electroluminescence layer 300 on the substrate 100;

S350: forming a touch layer 500 that directly covers on the first planarization layer 400 on the substrate 100.

In summary, the organic electroluminescence device and the manufacturing method for the same utilizes the first planarization layer 400 to directly encapsulate the switching layer 200 and the organic electroluminescence layer 300, and no additional Thin Film Encapsulation (TFE) layer is required. Accordingly, the thickness of the production is reduced and the cost is saved at the same time.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. An organic electroluminescence device, comprising:
a substrate;
a switching layer disposed on the substrate, and the switching layer includes multiple switching elements arranged as a matrix;
an organic electroluminescence layer disposed on the switching layer, the organic electroluminescence layer includes multiple organic electroluminescence elements arranged as a matrix, the organic electroluminescence elements are controlled to emit light through corresponding switching elements;
a first planarization layer disposed on the substrate, covering on the switching layer and the organic electroluminescence layer; and
a touch layer disposed on the substrate and covering on the first planarization layer.

2. The organic electroluminescence device according to claim 1, wherein, the switching element includes:
an active layer disposed on the substrate;
a gate insulation layer disposed on the active layer;
a gate electrode disposed on the gate insulation layer;
an interlayer dielectric layer disposed on the substrate, covering on the active layer, the gate insulation layer and the gate electrode, wherein the interlayer dielectric layer is provided with a first vias hole, and the first vias hole exposes the active layer;
a source electrode and a drain electrode disposed on the interlayer dielectric layer, wherein the source electrode and the drain electrode are respectively contacted with the active layer which is exposed through the first vias hole; and
a second planarization layer disposed on the interlayer dielectric layer, and covering on the source electrode and the drain electrode, wherein the second planarization layer is provided with a second vias hole, and the second vias hole exposes the drain electrode.

3. The organic electroluminescence device according to claim 2, wherein, the switching element further includes: a buffering layer disposed between the active layer and the substrate and between the interlayer dielectric layer and the substrate.

4. The organic electroluminescence device according to claim 2, wherein, a material of the active layer is amorphous silicon, low temperature polysilicon, carbon nanotube, graphene or metal oxide semiconductor.

5. The organic electroluminescence device according to claim 3, wherein, a material of the active layer is amorphous silicon, low temperature polysilicon, carbon nanotube, graphene or metal oxide semiconductor.

6. The organic electroluminescence device according to claim 2, wherein, the electroluminescence element comprises:
a bottom electrode disposed on the second planarization layer, and the bottom electrode is contacted with the exposed drain electrode through the second vias hole;
a pixel definition layer disposed on the second planarization layer and covering on the bottom electrode, the pixel definition layer has a third vias hole, and the third vias hole exposes the bottom electrode;
an organic light-emitting layer group disposed on the exposed bottom electrode; and
a top electrode disposed on the organic light-emitting layer group;
wherein, the first planarization layer is disposed on the pixel definition layer, and covering on the top electrode.

7. The organic electroluminescence device according to claim 6, wherein, from the bottom electrode to the top electrode, the organic light-emitting layer group sequentially includes: a hole injection layer, a hole transport layer, an emitting layer, an electrode transport layer and an electrode injection layer.

8. The organic electroluminescence device according to claim 1, wherein, the touch layer includes:
a first insulation layer disposed on the substrate and covering on the first planarization layer;
a touch electrode layer disposed on the first insulation layer; and
a second insulation layer disposed on the touch electrode layer.

9. The organic electroluminescence device according to claim 1, wherein, the substrate is a flexible substrate.

10. The organic electroluminescence device according to claim 1, wherein, the substrate is transparent, translucent or opaque.

11. The organic electroluminescence device according to claim 9, wherein, the substrate is transparent, translucent or opaque.

12. A manufacturing method for the organic electroluminescence device as claimed in claim 1, wherein, the manufacturing method comprises:
providing a substrate;
forming multiple switching elements arranged as a matrix on the substrate in order to form a switching layer;
forming multiple organic electroluminescence elements arranged as a matrix on the switching layer in order to form an organic electroluminescence layer, and each organic electroluminescence element is controlled to emit light by a corresponding switching element;
forming a first planarization layer that directly covers on the switching layer and the organic electroluminescence layer on the substrate; and
forming a touch layer that directly covers on the first planarization layer on the substrate.
